(19) United States
(12) Patent Application Publication
(10) Pub. No.: US 2025/0233565 A1
(43) Pub. Date: Jul. 17, 2025

(54) CHIP WITH CASCODE CIRCUITS

(71) Applicant: Infineon Technologies AG, Neubiberg (DE)

(72) Inventors: Hans Christoph Lehmann, München (DE); Jaromir Schindler, Hranice n. M (CZ)

(21) Appl. No.: 19/015,773

(22) Filed: Jan. 10, 2025

(30) Foreign Application Priority Data
Jan. 12, 2024 (DE) 10 2024 100 963.2

(51) Int. Cl. H03F 3/45

(52) U.S. Cl. CPC H03F 3/45255; H03F 2203/45024; H03F 2203/45056

(57) ABSTRACT

According to one exemplary embodiment, a chip is described, comprising a plurality of cascode circuits, wherein each cascode circuit has at least one cascode having at least one respective cascode transistor, a voltage generation circuit which is set up to generate control voltages for controlling the cascode transistors of the cascode circuits, a respective transistor circuit for each cascode, which is connected between the voltage generation circuit and the cascode, has a respective source follower and is set up to generate a cascode transistor control voltage for the at least one cascode transistor of the cascode by means of the respective source follower from a respective control voltage of the control voltages generated by the voltage generation circuit.

### REFERENCE TO RELATED APPLICATIONS

This application claims priority to German Patent Application 10 2024 100 963.2, filed on Jan. 12, 2024, the contents of which are hereby incorporated by reference in their entirety.

### TECHNICAL FIELD

Exemplary embodiments generally relate to chips with cascode circuits.

### BACKGROUND

Future technologies are leading to ever smaller transistors, and the reliability of the transistors is becoming increasingly important, especially for automotive products that must be error-free throughout their service life. As the limits of the allowable voltage ranges for smaller components are becoming lower all the time, it may be necessary to handle high voltages of circuit parts that do not have a corresponding rated voltage. An example of this is input/output interfaces that should be tolerant to surge voltages.

For example, a 5V device (in other words, a device with a 5V power supply and also with 5V input/output interfaces) may be provided that is to be used with transistors that have a lower operating voltage than 5V, e.g. 3.3V.

### SUMMARY

One approach to enable this is to use cascodes, in which a higher voltage is apportioned among multiple transistors, which can therefore be designed for a lower voltage rating. However, the cascode transistors of the cascodes must be supplied with suitable cascode voltage and approaches are therefore desirable in which this can be achieved efficiently (with low chip area requirement) and robustly (e.g. switching operations on one cascode should not affect another cascode).

According to one exemplary embodiment, a chip is provided comprising a plurality of cascode circuits, wherein each cascode circuit has at least one cascode having at least one respective cascode transistor, a voltage generation circuit which is set up to generate control voltages for controlling the cascode transistors of the cascode circuits, a respective transistor circuit for each cascode, which is connected between the voltage generation circuit and the cascode, has a respective source follower and is set up to generate a cascode transistor control voltage for the at least one cascode transistor of the cascode by means of the respective source follower from a respective control voltage of the control voltages generated by the voltage generation circuit.

### BRIEF DESCRIPTION OF THE DRAWINGS

The figures do not reflect the actual proportions but are intended to be used to illustrate the principles of the various exemplary embodiments. Various exemplary embodiments are described below with reference to the following figures.

FIG. 1 shows an electronic device according to an embodiment.

FIG. 2 shows an output driver for a pad according to an embodiment.

FIG. 3 shows an output driver according to an embodiment.

FIG. 4 shows an output driver according to an embodiment.

FIG. 5 shows an output driver according to an embodiment that extends the example of FIG. 3 to include feedback control.

FIG. 6 shows an output driver according to an embodiment that extends the example of FIG. 3 to include guide modules.

FIG. 7 shows an example in which the guide modules are implemented by a respective capacitor.

FIG. 8 shows an example in which the guide modules are implemented by a respective boost circuit.

FIG. 9 shows an example of an output driver according to another embodiment.

FIG. 10 shows an example of an output driver according to another embodiment.

FIG. 11 shows an example of an output driver according to another embodiment.

FIG. 12 shows an input circuit according to an embodiment.

FIG. 13 shows an input circuit according to another embodiment.

FIG. 14 shows a chip according to an embodiment.

### DETAILED DESCRIPTION

The following detailed description refers to the accompanying figures, which show details and exemplary embodiments. These exemplary embodiments are described in such detail that a person skilled in the art can carry out the invention. Other embodiments are also possible and the exemplary embodiments can be changed in structural, logical and electrical terms without departing from the subject matter of the invention. The various exemplary embodiments are not necessarily mutually exclusive; rather, various embodiments can be combined with one another to produce new embodiments. In the context of this description, the terms “connected”, “attached” and “coupled” are used to describe both a direct and an indirect connection, a direct or indirect attachment and a direct or indirect coupling.

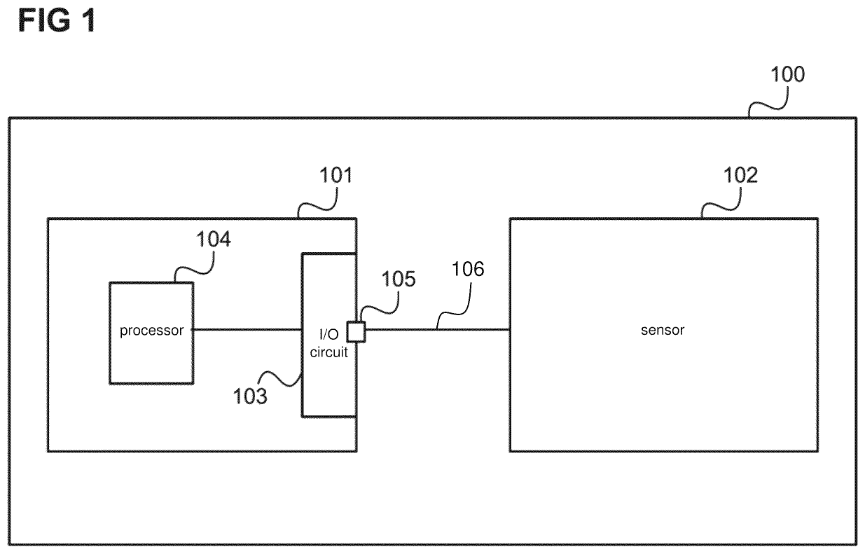

FIG. 1 shows an electronic device 100 according to an embodiment.

The electronic device 100 is, for example, an electronic control unit (ECU), in particular for a vehicle, but may also be a control unit or a data processing unit for other devices such as machines, power generators, etc.

The electronic device 100 comprises two electronic components 101, 102, for example a (data processing) chip 101 and a sensor 102 (which can also be realized as a chip or may contain such a chip). However, this is only used in the following as an example and the electronic components 101, 102 can also be other components and they do not need to be also part of the same electronic device, but can also be arranged separately from each other.

The chip 101 contains an input/output circuit 103, e.g. according to an I/O cell from a corresponding library. The input/output circuit 103 is connected, for example, to a processor 104 in the chip 101 on the one hand, and on the other hand to a pad 105 of the chip 101. A connecting line 106 connects the pad 105 to the sensor 102.

A main feature of an I/O cell is the connection of low-voltage on-chip signals (core voltage VDD, e.g. 3.3V) to higher-voltage off-chip signals (pad voltage VDDP, e.g. 5V) and vice versa. Both the input direction (off-chip=>on-chip, e.g. when receiving signals from the sensor) and the output direction (on-chip=>off-chip, e.g. when controlling the sensor or another circuit) can be supported.

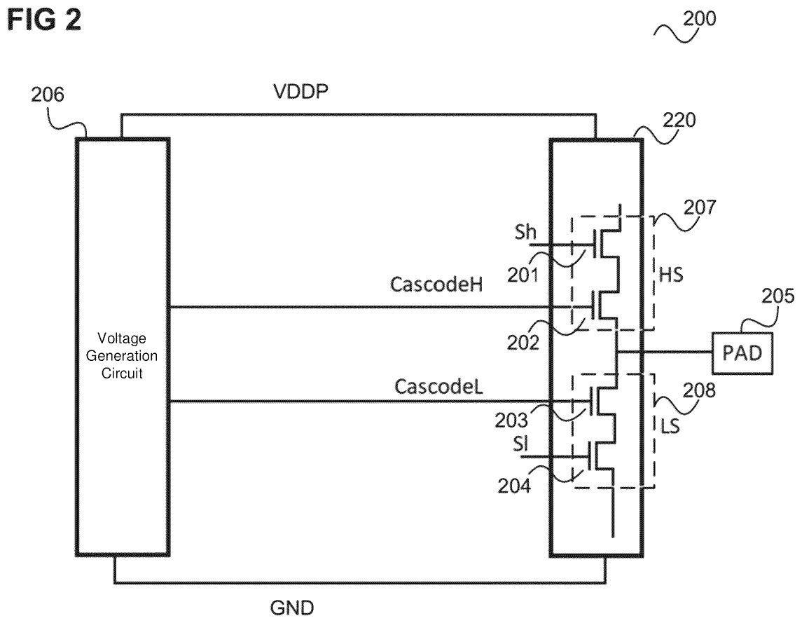

If the technology in which the chip 101 is manufactured comprises only components that are not able to withstand the pad voltage over an extended period of time, a stacking concept can be used, as shown in FIG. 2 using the example of an output driver.

FIG. 2 shows an output driver 200 for a pad 205 according to an embodiment.

Two (or more) first components (in the exemplary embodiments described herein these are field effect transistors (FETs), e.g. nMOS and/or pMOS) 201, 202 are connected in series to generate a HS (high-voltage side, high-side) driver 207, and two (or more) secondary devices (FETs) 203, 204 are used in series to generate a low-voltage side, low-side) driver 208. The HS driver 207 and the LS driver 208 are each implemented as a cascode (in this example with two levels, but more are also possible). Together they form a cascode circuit 220.

The connection point between HS driver 207 and LS driver 208 is connected to the pad 205. The HS driver 207 is connected between the high pad supply potential (VDDP) and pad 205, and the LS driver 208 is connected between pad 205 and the low pad supply potential (GND).

In this design, the pad voltage between VDDP and pad 205, or pad 205 and GND, is apportioned between the two modules 201, 202 of the HS driver 207 or 203, 204 of the LS driver 208, in such a way that each individual component 201-204 sees only a voltage that it can handle. For example, the pad voltage can be up to 5V and the components 201-204 are only 3.3V components. (Another example of the voltage ratio is VDDP=3.3V and the components 201, 202 are rated for 1.8V).

In the following, the devices of the components 202, 203 connected directly to the PAD are referred to as cascode transistors and the other two components 201, 204, which are connected to VDDP or GND, are referred to as switching transistors. The switching transistors 201, 204 are activated by signals Sh and Sl (which are also referred to as switching transistor control voltages). The gates of the cascode transistors 202, 203 are supplied with voltages CascodeH and CascodeL generated internally by an intermediate voltage generation circuit 206, which activate them in such a way that the voltage VDDP is apportioned correctly and none of the four components 201-204 is destroyed.

Since the internally generated voltages CascodeH and CascodeL should be available as soon as the pad voltage VDDP is applied to the pad 205, the intermediate voltage generation circuit 206 is designed, for example, as a voltage divider circuit which generates the voltages from VDDP but typically cannot drive large currents, as otherwise a large DC (direct current) consumption would be required for each individual I/O cell. The intermediate voltage generation circuit 206 can also be implemented in other ways, but then typically requires a certain start-up time, which means stress for the components 201-204 since then the voltages CascodeH and CascodeL are not immediately available with the pad voltage VDDP, and shortens their service life. It should be noted in this regard that the stacking of the components 201-204 leads to sharp edges at the source and drain of the cascode transistors 202, 203 during the switching phases (signal change of Sh and Sl). Since each cascode transistor 202, 203 has a parasitic coupling to its gate (more generally control input, e.g. to a control pin), to which CascodeH or CascodeL is supplied, the respective internally generated control voltage CascodeH or CascodeL varies during the switching process, which can lead to voltages on the stacked components which are outside their permissible range and may adversely affect the switching behavior. To avoid this, e.g. a large capacitor can be connected to the control pins of the cascode transistors 202, 203, which requires space, however, and must be charged during a start-up phase, which prolongs the start-up time.

In view of the above, according to various embodiments a driver concept for cascodes (in the following examples with two stages, but more stages are also possible) is provided to increase the accuracy and to improve the reliability of the stacked transistors used (i.e. the components 201 to 204 in FIG. 2) provided, which nevertheless allows fast switching. This allows transistors from a low-voltage to be used for higher pad voltages without shortening their service life.

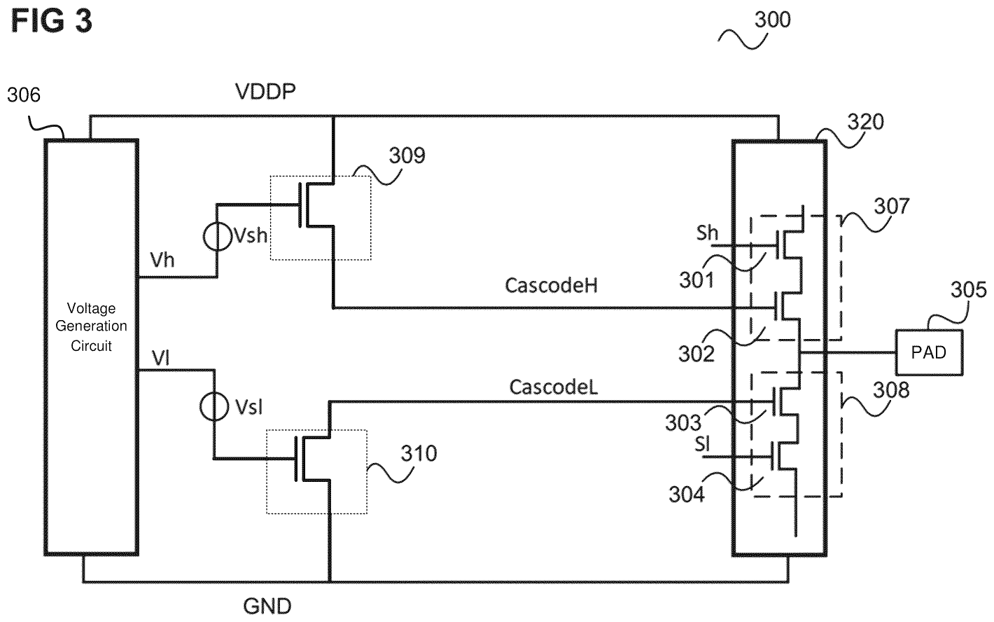

According to various embodiments, a circuit is inserted between the block that generates the cascode voltages with low driver potential (intermediate voltage generation circuit 206 in FIG. 2) and the gates (e.g. control pins) of the cascode transistors, which must be stabilized due to the parasitic coupling, as shown in FIG. 3 which illustrates this basic concept.

FIG. 3 shows an output driver 300 according to an embodiment.

As described with reference to FIG. 2, the output driver 300 comprises an HS driver 307, formed by a first switching transistor 301 and a first cascode transistor 302, and an LS driver 308, formed by a second switching transistor 304 and a second cascode transistor 303, the connecting node of which is connected to a pad 305, as well as an intermediate voltage generation circuit 306. The HS driver 307 and the LS driver 308 form a cascode circuit 320.

In contrast to the output driver 200 of FIG. 2, the voltages Vh and Vl generated by the intermediate voltage generation circuit 306 are not used directly as control voltages CascodeH and CascodeL for the cascode transistors 302, 304, but the output driver 300 includes buffering for the control signals Vh and Vl, via which the voltages CascodeH and CascodeL are controlled.

Specifically, a first source follower 309 receives the voltage Vh shifted by a voltage Vsh (at its gate, generally control input) and generates CascodeH (it is supplied from VDDP) and a second source follower 310 receives the voltage Vl shifted by a voltage Vsl (at its gate) and generates CascodeL (it is supplied from GND).

The source follower is understood to mean a field effect transistor in a common drain connection. The input voltage is the shifted voltage Vh or Vl and the output voltage is CascodeH or CascodeL. VDDP is the supply voltage.

By boosting the control voltage Vh for a voltage drop Vsh and driving a transistor as source follower 309, which generates a voltage loss with a similar voltage drop Vsh, the cascode control voltage CascodeH follows with a similar voltage level to Vh. However, the driver capability is now much higher, since the current is drawn directly from the supply (VDDP) as soon as the voltage in CascodeH falls below Vh. The same applies to the cascode control voltage CascodeL by using the second source follower 310.

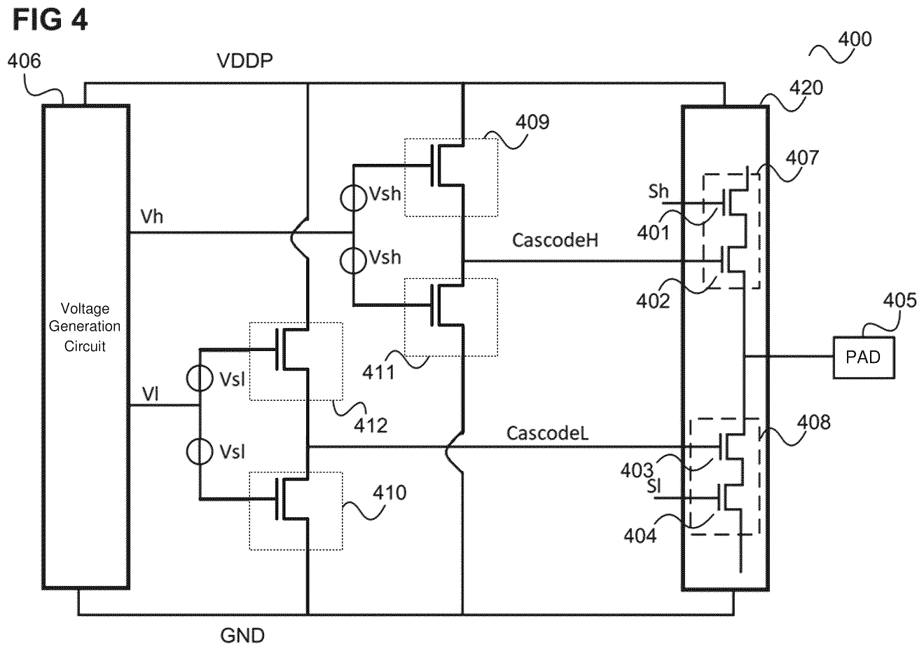

Such a buffer can be added for both directions of the possible switching noise at the gate (e.g. control pin) of the respective cascode transistor 302, 304, as illustrated in FIG. 4.

FIG. 4 shows an output driver 400 according to an embodiment.

Like the output driver 300 of FIG. 3, the output driver 400 contains an HS driver 407 formed by a first switching transistor 401 and a first cascode transistor 402, and an LS driver 408 formed by a second switching transistor 403 and a second cascode transistor 404, the connecting node of which is connected to a pad 405, as well as an intermediate voltage generation circuit 406 (e.g. implemented as a voltage divider circuit), a first source follower 409 and a second source follower 410. The HS driver 407 and the LS driver 408 form a cascode circuit 420.

In addition, the output driver 400 contains a third source follower 411, which receives (at its gate) the voltage Vh shifted by the voltage Vsh, is supplied from GND and the output of which is connected to the output of the first source follower 409, so that together they produce CascodeH.

Similarly, the output driver 400 contains a fourth source follower 412, which receives (at its gate) the voltage Vl shifted by the voltage Vsl, is supplied from VDDP and the output of which is connected to the output of the second source follower 410, so that together they produce CascodeL.

This allows both a decrease and an increase of the voltage CascodeH or CascodeL to be compensated in order to maintain the permissible voltage range for all transistors of the HS driver 407 and LS driver 408. This decouples the generated internal voltages Vh, Vl from the switching noise, making them more stable and reducing the DC power consumption of the intermediate voltage generation circuit 406, as this only needs to drive a small noiseless load. In addition, the noise generated by the coupling to the gate of the respective cascode transistor 402, 403 can be compensated by an almost unlimited current during the switching phase (and the parasitic capacitance can be charged accordingly), without this leading to an overall increase in the DC power consumption.

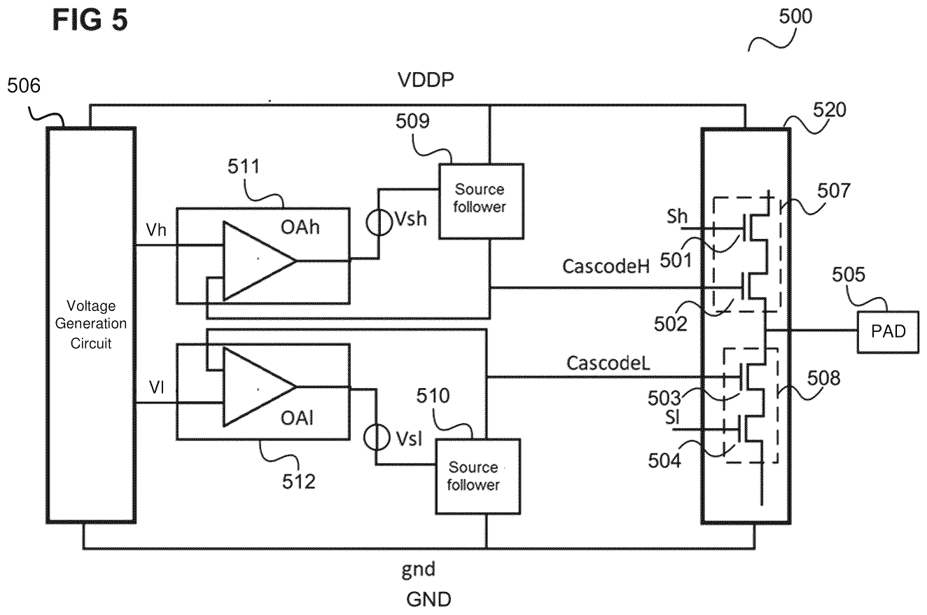

FIG. 5 shows an output driver 500 according to an embodiment that extends the example of FIG. 3 to include feedback control.

Like the output driver 300 of FIG. 3, the output driver 500 contains an HS driver 507 formed by a first switching transistor 501 and a first cascode transistor 502, and an LS driver 508 formed by a second switching transistor 504 and a second cascode transistor 503, the connecting node of which is connected to a pad 505, as well as an intermediate voltage generation circuit 506 (e.g. implemented as a voltage divider circuit), a first source follower 509 and a second source follower 510. The HS driver 507 and the LS driver 508 form a cascode circuit 520.

In contrast to the output driver 300 of FIG. 3, the voltages Vh and Vl between the intermediate voltage generation circuit 506 and the respective source follower 509, 510 are buffered by a respective buffer circuit 511, 512.

In the driver circuit 300 of FIG. 3, a current could flow into or out of the intermediate voltage generation circuit 306 due to the voltage shift (Vsh and Vsl). A mismatch between the two currents that cause the voltage shift by Vsh and Vsl could lead to an error in the voltage generation, which in turn would result in a voltage shift at the gates of the cascode transistors 302, 303. By using the (real) buffer circuits 511 and 512, the current flow (potentially caused by Vsh and Vsl) into or out of the intermediate voltage generation circuit 506 is prevented and thus a voltage shift at the gates of the cascode transistors 502, 503 is prevented. In addition, the buffer circuits 511, 512 can be used as a control loop for each similar intermediate node or the control voltages CascodeH and CascodeL finally used (as shown in FIG. 5 by feeding CascodeH and CascodeL back to the respective operational amplifier of the respective buffer circuit 511, 512), thereby further increasing the accuracy. The mismatch of the voltage shifts up and down is thus replaced by the offset of the buffer circuit and can be reduced in a much better way.

The buffering as described with reference to FIG. 5 can also be applied to the additional source followers 411, 412 in the structure of FIG. 4.

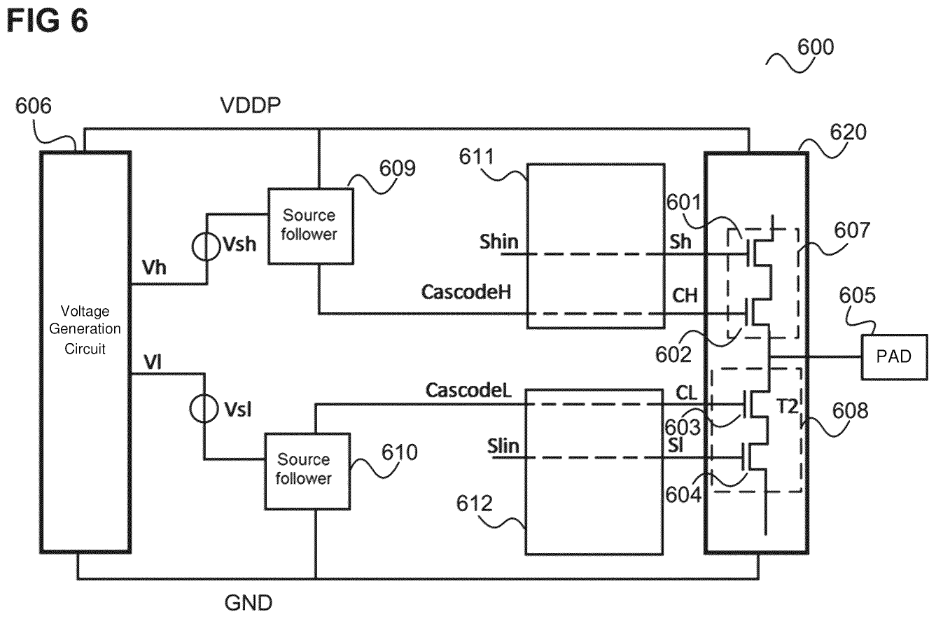

FIG. 6 shows an output driver 600 according to an embodiment that extends the example of FIG. 3 to include guide modules 611, 612.

Like the output driver 300 of FIG. 3, the output driver 600 contains an HS driver 607 formed by a first switching transistor 601 and a first cascode transistor 602, and an LS driver 608 formed by a second switching transistor 604 and a second cascode transistor 603, the connecting node of which is connected to a pad 605, as well as an intermediate voltage generation circuit 606 (e.g. implemented as a voltage divider circuit), a first source follower 609 and a second source follower 610. The HS driver 607 and the LS driver 608 form a cascode circuit 620.

A guide module 611, 612 is provided for each of the cascode transistor control voltages CascodeH and CascodeL, which can influence the respective cascode transistor control voltage in advance. For example, when the switching transistor control signal Sh or Sl of a switching transistor 601, 604 switches one of the largest circuits of the chip 101, such as the power stage of a typical output driver, it couples interference signals into the cascode transistor control voltages CascodeH and CascodeL. The respective guide module 611, 612 can cause a shift in the respective cascode voltage CascodeH or CascodeL depending on the switching transistor control signals Sh and/or Sl by any kind of circuit.

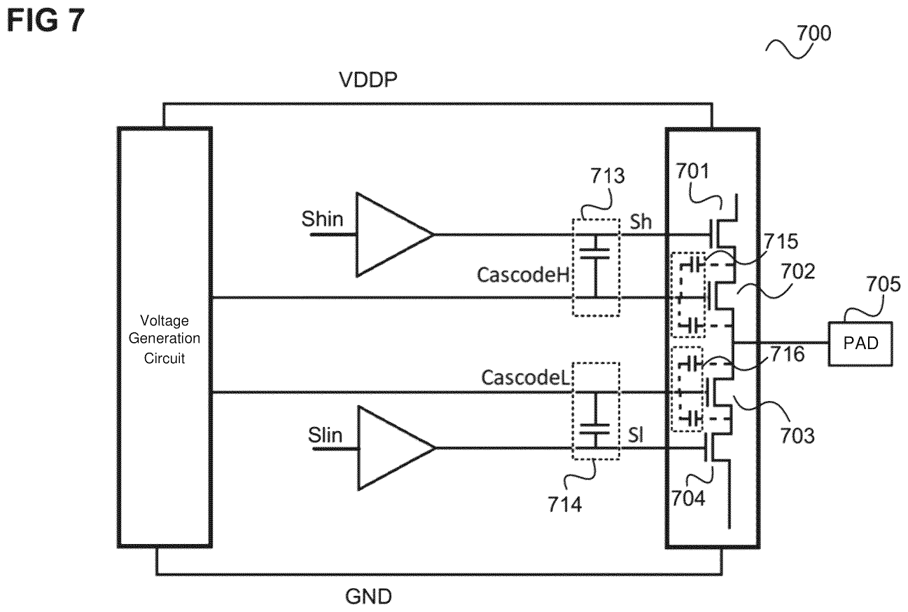

FIG. 7 shows an example in which the guide modules 611, 612 are implemented by a respective capacitor 713, 714 between the gate of the respective switching transistor 701, 704 and the gate of the respective cascode transistor 702, 703.

In FIG. 7 the source followers are not shown but they may be provided as described with reference to FIG. 3, 4 or 5.

The use of capacitors 713, 714 provides a simple solution to the coupling of noise into the cascode transistor control voltages CascodeH and CascodeL due to parasitic couplings 715, 716. Each capacitor 713, 714 can shift the cascode control voltage away from the intended voltage by the expected value of the voltage coupled in, in order to be pulled back into the range of the intended voltage by the parasitic couplings 715, 716 during switching.

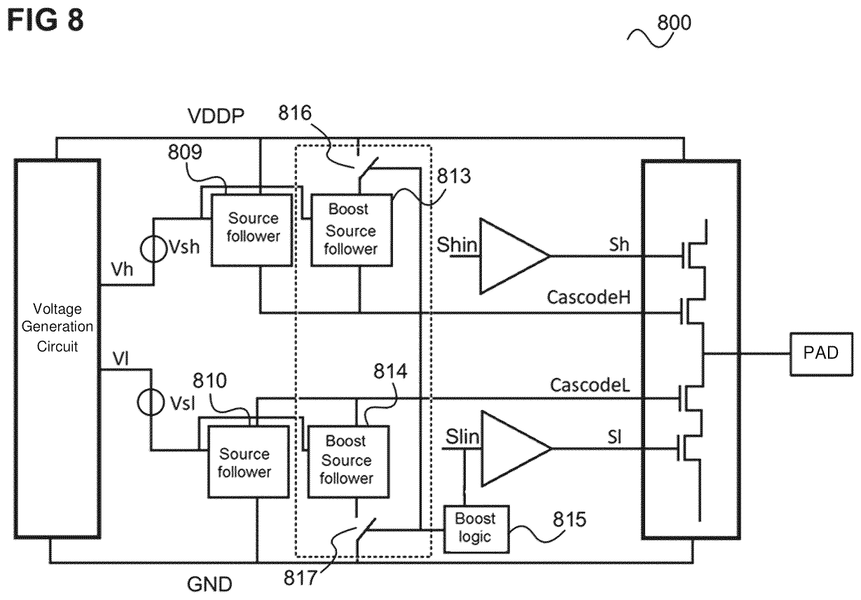

FIG. 8 shows an example in which the guide modules 611, 612 are implemented by a respective boost circuit 813, 814 in parallel with the source followers 809, 810, which are switched on in order to amplify the cascode transistor control voltages CascodeH and CascodeL and thus achieve the intended voltage faster and/or to eliminate interference as described with reference to FIG. 7. According to one embodiment these are themselves source followers and are supplied and controlled in the same way as the source followers 809, 810 (i.e. their gates (generally control inputs) are connected e.g. to those of the source followers 809, 810).

For example, a logic circuit 815 is provided, which activates the supply of the boost circuits 813, 814 (shown here by switches 816, 817) when Sh and Sl are switched over.

As shown in FIG. 7 and FIG. 8, the switching transistor control signals Sh and Sl, for example, originate from control signals Shin and Slin supplied to buffers.

The guide modules from FIG. 7 and FIG. 8 can also be linked (combined).

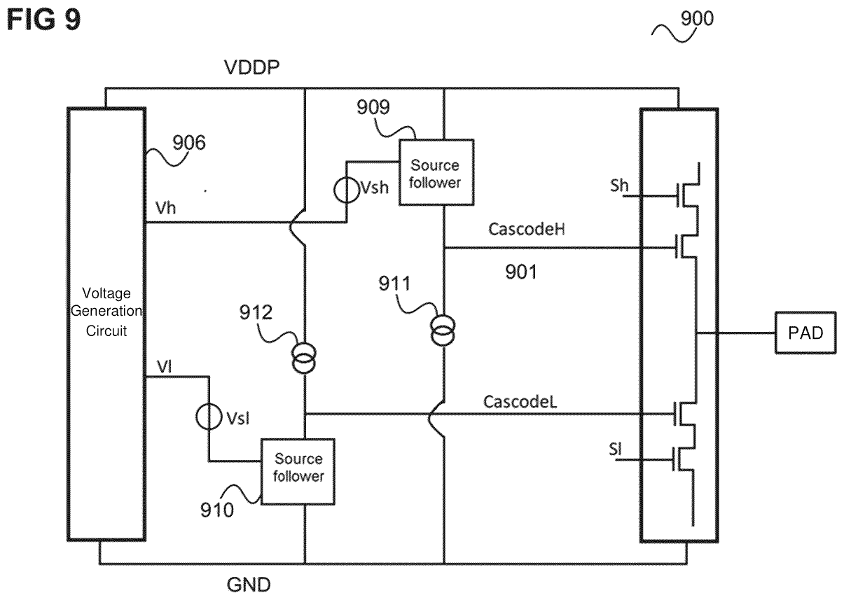

FIG. 9 shows an example of an output driver 900 (based on the output driver 300 of FIG. 3), in which the output of the first source follower 909 is connected to VDDP via a first current source 911 and the output of the second source follower 910 is connected to GND via a second current source 912.

This has the advantage that, in a voltage range in which the intermediate voltage generation circuit 906 is not yet fully operating and/or it cannot switch the source follower on yet, or the desired target differential voltage range for the CascodeH (VDDP-CasccodeH) and CascodeL (CasccodeL-VSSP) voltages is above the existing VDDP voltage and the transistors are therefore protected but the gate voltage would be further restricted by the second source follower, the maximum supply voltage is applied to the cascode transistors. This ensures that the full performance can be achieved even with lower VDDP voltages.

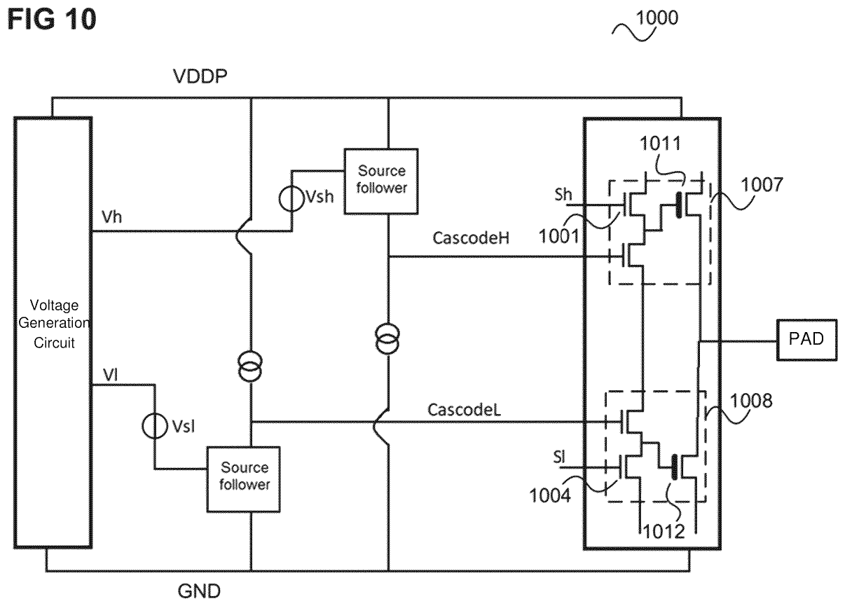

FIG. 10 shows an example of an output driver 1000 (based on the output driver 900 of FIG. 9), in which the output stage is not implemented by stacked transistors, but additional transistors 1007, 1008 (e.g. DMOS or high-voltage transistors with a VDS voltage which meet the 5V requirements, but the gate still, for example, only allows the 3.3V) are present instead. Then the source followers etc. in the output driver path can only be used for internal circuits such as the output stage driver and the signal level shifters. In other words this example shows that not only circuits connected to a PAD can be driven, but also circuits that are only used internally.

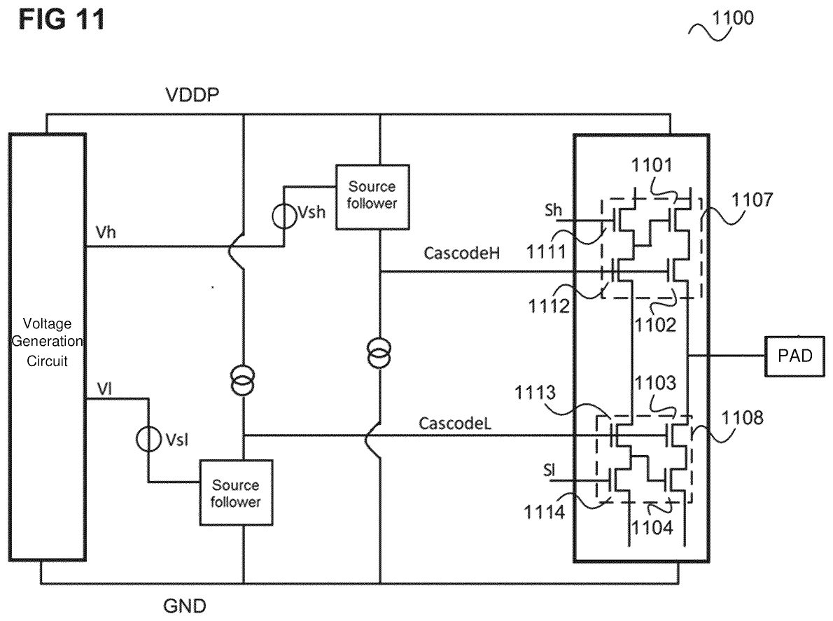

FIG. 11 shows an example of an output driver 1100 (based on the output driver 900 of FIG. 9), in which in addition to the cascodes formed by the transistors 1101-1104, a further stage with two cascodes formed by a third switching transistor 1111 and a third cascode transistor 1112 or a fourth switching transistor 1114 and a fourth cascode transistor 1113 are present.

The example of FIG. 11 is comparable to the example of FIG. 10, except that in FIG. 11 the additional (e.g. DMOS) transistors of the output stage have again been replaced by the stacked circuit from FIGS. 2-9, and the driver from the stage before it is additionally shown.

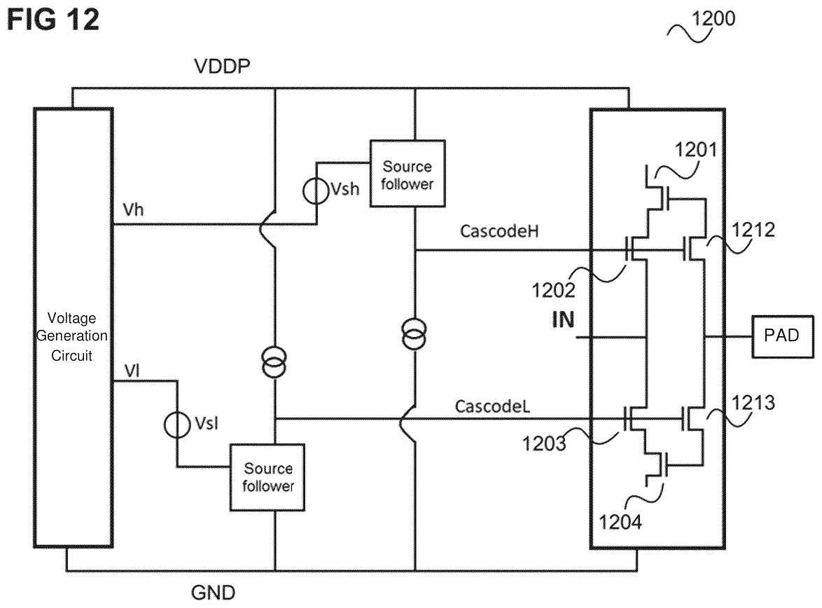

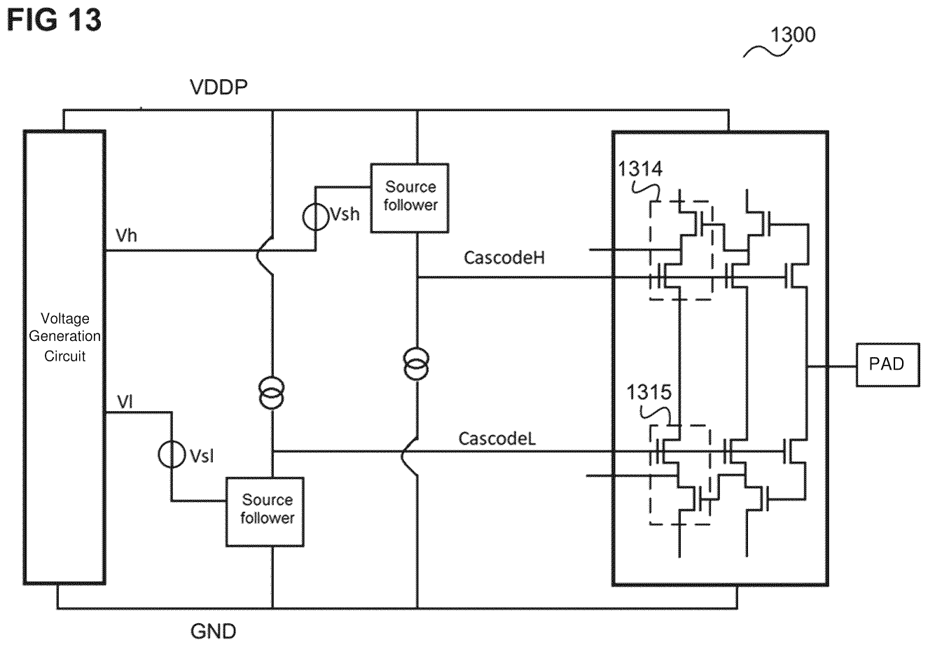

In each of the above examples, an output driver was described, i.e. an output signal was designed to be output via the pad, wherein the output signal is determined by the sequence of states of Sh and Sl, which is defined e.g. by the processor 104 (optionally via an interface circuit of the chip 101), in order to send data. However, the concepts described above in connection with an output driver can also be used for receiving data via the pad. The switching transistors are then not controlled by the signals Sh and Sl, but by the signal applied to the pad. Examples of this are shown in FIG. 12 and FIG. 13.

FIG. 12 shows an input circuit 1200 according to an embodiment.

The input circuit 1200 is configured analogously to the output driver 1100 of FIG. 11, but these gates of the first switching transistor 1201 and the second switching transistor 1204 are connected to the pad 1205 via the third cascode transistor 1212 and the fourth cascode transistor 1213 respectively, so that on the pad 1205 of the second electronic component 102 (e.g. a sensor) the levels applied to the pad 1205 control the first switching transistor 1201 and the second switching transistor 1204. The third switching transistor 1111 and the fourth switching transistor 1114 are omitted.

The connection node between the first cascode transistor 1202 and the second cascode transistor 1203 forms the receiving node and is connected, for example, to an input of the processor 104 or an interface circuit of the chip 101.

FIG. 13 shows an input circuit 1300 according to a further embodiment.

Similarly to the way in which the output driver 1100 of FIG. 11 is extended by two further cascodes with respect to the output driver 900 of FIG. 9, the input circuit 1300 corresponds to an extension of the input circuit 1200 of FIG. 12 by a further stage with two additional cascodes 1314, 1315 (added here to the left because in contrast to the output driver 1100 of FIG. 11 the pad is used as an input).

In addition, two complementary input nodes are used in this example (connection nodes between the switching transistor and cascode transistor of the added cascodes).

The circuit of FIG. 13 is comparable to that of FIG. 12, wherein an additional internal buffer cell is included here, which is not connected to the pad. An additional difference compared to FIG. 12 is that the connection node of 1202 and 1203 is not used as an input signal (this signal is often again e.g. 5V), but now voltage amplitudes limited by the voltages CascodeH and CascodeL. This means that the nearest pMOS transistor (similar to 1201) and nMOS transistor (similar to 1204) (as also shown in FIG. 13) can be activated again, which means that the amplitude of the signal is reduced and the activated transistors are not destroyed.

As explained above, the connection of the unit that generates the cascode voltages (referred to in the examples above as the intermediate voltage generation circuit) via source followers means that it is possible to prevent noise in the cascodes (such as the HS driver and the LS driver in the above embodiments, which, as in the examples of FIGS. 11 and 13, may also each have multiple cascodes) from having a negative effect on the unit that generates the cascode voltages. This is particularly important when the intermediate voltage generation circuit supplies a large number of cascode circuits (with the same or with possibly at least partially different cascode transistor control voltages), as noise is prevented from propagating from one cascode circuit to other cascode circuits.

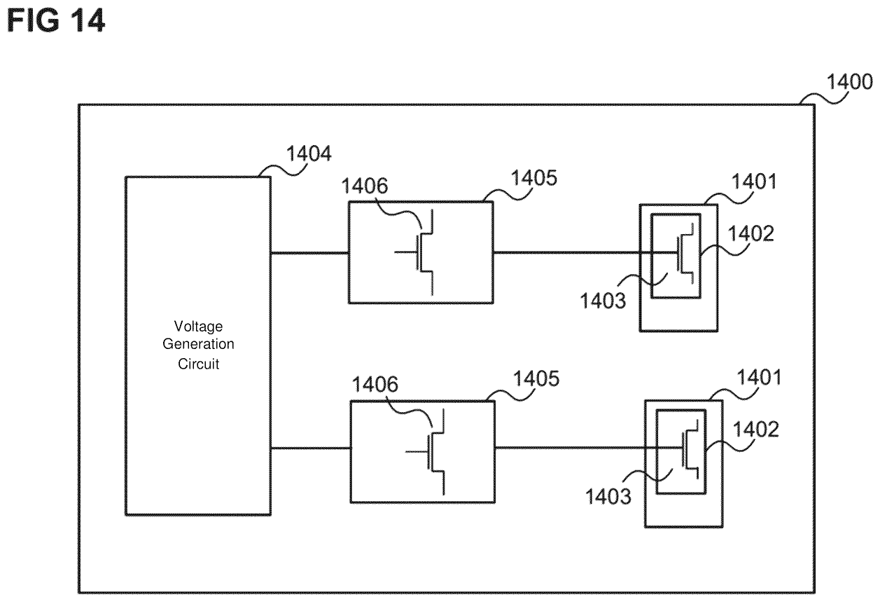

In summary, according to various embodiments, a chip is provided as shown in FIG. 14.

FIG. 14 shows a chip 1400 according to an embodiment.

The chip 1400 has a plurality of cascode circuits 1401, wherein each cascode circuit 1401 comprises at least one cascode 1402 having at least one respective cascode transistor 1403.

The chip 1400 further comprises a voltage generation circuit 1404, which is set up to generate control voltages for controlling the cascode transistors 1403 of the cascode circuits 1401.

For each cascode 1402, the chip 1400 also has a respective transistor circuit 1405 which is connected between the voltage generation circuit 1404 and the cascode 1402, has a respective source follower 1406 and is set up, by means of the respective source follower 1406, to generate a cascode transistor control voltage for the at least one cascode transistor 1403 of the cascode 1402 from a respective control voltage of the control voltages generated by the voltage generation circuit 1404.

According to various embodiments, in other words, the voltage generation circuit supplies a plurality of cascodes and is decoupled from the cascodes by means of source followers in such a way that voltage fluctuations in one cascode do not affect the other cascodes.

The procedure according to FIG. 14 enables a stabilized switching behavior of a plurality of cascodes, which increases the reliability and service life of the components involved. The signal frequency can be increased and the jitter caused by coupling between the cascodes can be reduced, since a reduction in the gate voltages of the cascode transistors can be limited. The procedure has small space requirements, e.g. in comparison with the use of capacitances for stabilizing the cascode transistor control voltages (even if these may be additionally provided, as in the example of FIG. 7).

Various exemplary embodiments are specified below.

Exemplary embodiment 1 is a chip, as described with reference to FIG. 14.

Embodiment 2 is a chip according to exemplary embodiment 1, wherein the respective transistor circuit increases the respective control voltage of the control voltages generated by the voltage generation circuit according to a voltage drop across the source follower, and the respective source follower is controlled with the increased control voltage.

Exemplary embodiment 3 is a chip according to exemplary embodiment 1 or 2, wherein for each cascode the respective transistor circuit has two respective source followers and is set up to generate the cascode transistor control voltage for the at least one cascode transistor of the cascode by means of the source followers from the respective control voltage of the control voltages generated by the voltage generation circuit, wherein one of the source followers is supplied from a high supply potential and one of the source followers from a low supply potential.

Exemplary embodiment 4 is a chip according to one of the exemplary embodiments 1 to 3, wherein the respective transistor circuit has a respective buffer circuit, which is set up to buffer the respective control voltage of the control voltages generated by the voltage generation circuit and wherein the respective source follower is controlled by means of the buffered control voltage.

Exemplary embodiment 5 is a chip according to one of the exemplary embodiments 1 to 4, comprising for each cascode a respective guide module, which is set up to supply the cascode transistor control voltage to the at least one cascode transistor and which is set up to compensate for fluctuations in the cascode transistor control voltage due to switching the cascode.

Exemplary embodiment 6 is a chip according to exemplary embodiment 5, wherein the respective guide module has a capacitor between a line with which the cascode transistor control voltage is supplied to the cascode transistor, and a line with which a switching transistor control voltage is supplied to a switching transistor of the cascode.

Exemplary embodiment 7 is a chip according to exemplary embodiment 5 or 6, wherein the respective guide module has a respective further source follower, which is switched on when switching the cascode so that it amplifies the cascode transistor control voltage.

Exemplary embodiment 8 is a chip according to exemplary embodiment 7, wherein the respective further source follower has the same supply as the respective source follower and/or the same voltage is fed to it at its control input as to the respective source follower.

Exemplary embodiment 9 is a chip according to one of the exemplary embodiments 1 to 8, wherein the source follower is supplied at a supply terminal by a supply potential corresponding to the supply potential of the cascode, and at the other from a current source.

Exemplary embodiment 10 is a chip according to one of the exemplary embodiments 1 to 9, wherein each of at least some of the cascodes has an output which is connected to a respective output terminal of the chip.

Embodiments 11 is a chip according to one of the exemplary embodiments 1 to 9, wherein each of at least some of the cascodes is set up to generate an output voltage which controls a respective output transistor of the chip.

Exemplary embodiment 12 is a chip according to one of the exemplary embodiments 1 to 9, wherein each of at least some of the cascodes is controlled by a voltage applied to a respective input terminal of the chip.

Exemplary embodiment 13 is a chip according to one of the exemplary embodiments 1 to 12, wherein the cascodes are at least partially connected in series, so that the plurality of cascode circuits each have a high-voltage-side driver and/or a low-voltage-side driver.

Exemplary embodiment 14 is a chip according to exemplary embodiment 13, wherein the cascodes are at least partially connected in parallel, so that the high-voltage-side drivers and/or the low-voltage side drivers are formed by a plurality of cascodes connected in parallel.

Exemplary embodiment 15 is a chip according to exemplary embodiment 14, wherein the cascode transistors of the cascode connected in parallel are controlled by the same cascode transistor control voltage.

Exemplary embodiment 16 is an electronic device having a chip according to one of the exemplary embodiments 1 to 15, wherein the cascodes are formed of transistors having a nominal voltage that is lower than an input voltage of an input circuit of the chip formed thereby, in the device and/or less than an output voltage of an output circuit of the chip formed thereby in the device.

Although the invention has been shown and described primarily with reference to specific embodiments, it should be understood by those familiar with the technical field that numerous modifications can be made thereto with regard to configuration and details, without departing from the essence and scope of the invention as defined by the claims hereinafter. The scope of the invention is therefore determined by the appended claims, and the intention is for all modifications to be encompassed which come under the literal meaning or the scope of equivalence of the claims.

### REFERENCE SIGNS

100 electronic device
101 electronic component, e.g. chip
102 electronic component, e.g. sensor
103 input/output circuit
104 processor
105 pad
106 connecting cable
200 output driver
201 switching transistor
202, 203 cascode transistors
204 switching transistor
205 pad
206 intermediate voltage generation circuit
207 HS driver
208 LS driver
220 cascode circuit
300 output driver
301 switching transistor
302, 303 cascode transistors
304 switching transistor
305 pad
306 intermediate voltage generation circuit
307 HS driver
308 LS driver
309, 310 source followers
320 cascode circuit
400 output driver
401 switching transistor
402, 403 cascode transistors
404 switching transistor
405 pad
406 intermediate voltage generation circuit
407 HS driver
408 LS driver
409, 412 source followers
420 cascode circuit
500 output driver
501 switching transistor
502, 503 cascode transistors
504 switching transistor
505 pad
506 intermediate voltage generation circuit
507 HS driver
508 LS driver
509, 510 source followers
511, 512 buffer circuit
520 cascode circuit
600 output driver
601 switching transistor
602, 603 cascode transistors
604 switching transistor
605 pad
606 intermediate voltage generation circuit
607 HS driver
608 LS driver
609, 610 source followers
611, 612 guide modules
620 cascode circuit
700 output driver
701 switching transistor
702, 703 cascode transistors
704 switching transistor
705 pad
713, 714 capacitors
715, 716 parasitic couplings
800 output driver
809, 810 source followers
813, 814 boost circuits
815 logic circuit
816, 817 switches
900 output driver
909, 910 source followers
911, 912 current sources
1000 output driver
1001, 1004 switching transistors
1007 HS driver
1008 LS driver
1011, 1012 additional transistors
1101 switching transistor
1102, 1103 cascode transistors
1104 switching transistor
1107 HS driver
1108 LS driver
1111 switching transistor
1112, 1113 cascode transistors
1114 switching transistor
1200 input circuit
1201 switching transistor
1202, 1203 cascode transistors
1204 switching transistor
1205 pad
1212, 1213 cascode transistors
1300 input circuit
1314, 1315 additional cascodes

What is claimed is:

1. A chip, comprising:
a plurality of cascode circuits, each cascode circuit having at least one cascode with at least one respective cascode transistor;
a voltage generation circuit which is set up to generate control voltages for controlling the cascode transistors of the plurality of cascode circuits,
a respective transistor circuit for each cascode, which is connected between the voltage generation circuit and the cascode, has a respective source follower and is set up to generate a cascode transistor control voltage for the at least one cascode transistor of the cascode by use of the respective source follower from a respective control voltage of the control voltages generated by the voltage generation circuit.

2. The chip as claimed in claim 1, wherein the respective transistor circuit increases the respective control voltage of the control voltages generated by the voltage generation circuit according to a voltage drop across the respective source follower, and the respective source follower is controlled with the increased control voltage.

3. The chip as claimed in claim 1, wherein for each cascode the respective transistor circuit has two respective source followers and is set up to generate the cascode transistor control voltage for the at least one cascode transistor of the cascode by use of the source followers from the respective control voltage of the control voltages generated by the voltage generation circuit, wherein one of the source followers is supplied from a high supply potential and one of the source followers from a low supply potential.

4. The chip as claimed in claim 1, wherein the respective transistor circuit has a respective buffer circuit, which is set up to buffer the respective control voltage of the control voltages generated by the voltage generation circuit and wherein the respective source follower is controlled using the buffered control voltage.

5. The chip as claimed in claim 1, comprising for each cascode a respective guide module, which is set up to supply the cascode transistor control voltage to the at least one cascode transistor and which is set up to compensate for fluctuations in the cascode transistor control voltage due to a switching of the cascode.

6. The chip as claimed in claim 5, wherein the respective guide module comprises a capacitor between a line with which the cascode transistor control voltage is supplied to the cascode transistor, and a line with which a switching transistor control voltage is fed to a switching transistor of the cascode.

7. The chip as claimed in claim 5, wherein the respective guide module has a respective further source follower, which is switched on when the cascode is switched so that it amplifies the cascode transistor control voltage.

8. The chip as claimed in claim 7, wherein the respective further source follower has the same supply as the respective source follower and/or the same voltage is fed to it at its control input as to the respective source follower.

9. The chip as claimed in claim 1, wherein the source follower is supplied at one supply terminal from a supply potential corresponding to the supply potential of the cascode, and at the other terminal from a current source.

10. The chip as claimed in claim 1, wherein each of at least some of the cascodes has an output which is connected to a respective output terminal of the chip.

11. The chip as claimed in claim 1, wherein each of at least some of the cascodes is set up to generate an output voltage which controls a respective output transistor of the chip.

12. The chip as claimed in claim 1, wherein each of at least some of the cascodes is controlled by a voltage applied to a respective input terminal of the chip.

13. The chip as claimed in claim 1, wherein the cascodes are at least partially connected in series, so that the plurality of cascode circuits each have a high- voltage-side driver and/or a low-voltage-side driver.

14. The chip as claimed in claim 13, wherein the cascodes are at least partially connected in parallel so that the high-voltage-side drivers and/or the low-voltage-side drivers are formed by a plurality of cascodes connected in parallel.

15. The chip as claimed in claim 14, wherein the cascode transistors of the parallel connected cascodes are controlled by the same cascode transistor control voltage.

16. An electronic device having a chip as claimed in claim 1, wherein the cascodes are formed of transistors having a nominal voltage which is less than an input voltage of an input circuit of the chip formed thereby in the electronic device and/or is less than an output voltage of an output circuit of the chip, formed thereby in the electronic device.

17. A chip, comprising:
a first switching transistor including a first terminal, a second terminal, and a control terminal, the first terminal of the first switching transistor coupled to a first DC voltage terminal;
a first cascode transistor including a first terminal, a second terminal, and a control terminal, the first terminal of the first cascode transistor coupled to the second terminal of the first switching transistor, and the second terminal of the first cascode transistor coupled to a conductive pad;
a second cascode transistor including a first terminal, a second terminal, and a control terminal, the first terminal of the second cascode transistor coupled to the second terminal of the first cascode transistor and the conductive pad;
a second switching transistor including a first terminal, a second terminal, and a control terminal, the first terminal of the second switching transistor coupled to the second terminal of the second cascode transistor, and the second terminal of the second switching transistor coupled to a second DC voltage terminal;
a first source follower transistor including a first terminal, a second terminal, and a control terminal, the first terminal of the first source follower transistor coupled to the first DC voltage terminal, and the second terminal of the first source follower transistor coupled to the control terminal of the first cascode transistor;
a second source follower transistor including a first terminal, a second terminal, and a control terminal, the first terminal of the second source follower transistor coupled to the control terminal of the second cascode transistor, and the second terminal of the second source follower transistor coupled to the second DC voltage terminal; and
a voltage generation circuit having a first output coupled to the control terminal of the first source follower transistor and having a second output coupled to the control terminal of the second source follower transistor.

18. The chip of claim 17, further comprising:
a third source follower transistor including a first terminal, a second terminal, and a control terminal, the first terminal of the third source follower transistor coupled to the second terminal of the first source follower transistor, the second terminal of the third source follower transistor coupled to the second DC voltage terminal, and the control terminal of the third source follower transistor coupled to the control terminal of the first source follower transistor; and
a fourth source follower transistor including a first terminal, a second terminal, and a control terminal, the first terminal of the fourth source follower transistor coupled to the second terminal of the second source follower transistor, the second terminal of the fourth source follower transistor coupled to the second DC voltage terminal, and the control terminal of the fourth source follower transistor coupled to the control terminal of the second source follower transistor.

19. The chip of claim 17, further comprising:
a first capacitor having a first capacitor terminal and a second capacitor terminal, the first capacitor terminal of the first capacitor coupled to the control terminal of the first switching transistor and the second capacitor terminal of the first capacitor coupled to the control terminal of the first source follower transistor; and
a second capacitor having a first capacitor terminal and a second capacitor terminal, the first capacitor terminal of the second capacitor coupled to the control terminal of the second switching transistor and the second capacitor terminal of the second capacitor coupled to the control terminal of the second source follower transistor.

20. The chip of claim 17, wherein the first switching transistor, the first cascode transistor, the second cascode transistor, the second switching transistor, the first source follower transistor, and the second source follower transistor are metal oxide semiconductor field effect transistors (MOSFETs).
